(19) United States
(12) Patent Application Publication
(10) Pub. No.: US 2013/0160834 A1
(43) Pub. Date: Jun. 27, 2013

(54) BACK-SIDE ELECTRODE OF P-TYPE SOLAR CELL, AND METHOD FOR FORMING THE SAME

(71) Applicants: AKIRA INABA, Kawasaki-shi (JP); TAKESHI KONDO, Kanagawa (JP)

(72) Inventors: AKIRA INABA, Kawasaki-shi (JP); TAKESHI KONDO, Kanagawa (JP)

(73) Assignee: E.I. DU PONT DE NEMOURS AND COMPANY, Wilmington, DE (US)

(21) Appl. No.: 13/337,602

(22) Filed: Dec. 27, 2011

(51) Int. Cl. H01L 31/0224; H01B 1/02; H01L 31/18

(52) U.S. Cl. 136/256; 438/98; 252/512; 257/E31.124

(57) ABSTRACT

The invention relates to a back-side electrode adjacently formed on silicon layer of p-type solar cell, comprises a conductive component comprising, before firing, (a) aluminum powder, (b) organic medium and (c) metal-containing component selected from the group consisting of (i) metal selected from the group consisting of Titanium(Ti), Manganese(Mn) and Cerium (Ce), and (ii) carbide, oxide, nitride, boride, carbonate, hydroxide and resinate of (i) metal.

### FIELD OF THE INVENTION

The present invention is directed to a back-side electrode formed on silicon layer of p-type solar cell, an aluminum paste used for forming such electrode and method of forming p-type silicon solar cells.

### TECHNICAL BACKGROUND OF THE INVENTION

A conventional solar cell structure with a p-type base has a negative electrode that is typically on the front-side or sun side of the cell and a positive electrode on the back-side. It is well known that radiation of an appropriate wavelength falling on a p-n junction of a semiconductor body serves as a source of external energy to generate hole-electron pairs in that body. The potential difference that exists at a p-n junction, causes holes and electrons to move across the junction in opposite directions and thereby give rise to flow of an electric current that is capable of delivering power to an external circuit. Most solar cells are in the form of a silicon wafer that has been metallized, i.e., provided with metal contacts which are electrically conductive.

During the formation of a silicon solar cell, an aluminum paste is generally screen printed and dried on the back-side of the silicon wafer. The wafer is then fired at a temperature above the melting point of the eutectic point of Aluminum and Silicon to form an aluminum-silicon melt, subsequently, during the cooling phase, an epitaxially grown layer of silicon is formed that is doped with aluminum. This layer is generally called the back surface field (BSF) layer, and helps to improve the energy conversion efficiency of the solar cell.

Most electric power-generating solar cells currently used are silicon solar cells. Process flow in mass production is generally aimed at achieving maximum simplification and minimizing manufacturing costs. Electrodes in particular are made by using a method such as screen printing from a metal paste.

An example of this method of production is described below in conjunction with FIG. 1. FIG. 1A shows a p-type silicon substrate 10. In FIG. 1B an n-type diffusion layer 20 of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer 20 is formed over the entire surface of the silicon substrate 10. The p-n junction is formed where the concentration of the p-type dopant equals the concentration of the n-type dopant; conventional cells that have the p-n junction close to the sun side, have a junction depth between 0.05 and 0.5 μm. After formation of this diffusion layer excess surface glass is removed from the rest of the surfaces by etching by an acid such as hydrofluoric acid in the manner shown in FIG. 1C. Next, an antireflective coating (ARC) 30 is formed on the n-type diffusion layer 20, to a thickness of between 0.05 and 0.1 μm in the manner shown in FIG. 10 by a process, such as, for example, plasma chemical vapor deposition (CVD). As shown in FIG. 1E, a front-side silver paste (front electrode-forming silver paste) 500, for the front electrode is screen printed and then dried over the antireflective coating 30. In addition, a back-side aluminum paste 60 and back-side silver or silver/aluminum paste 70 are then screen printed (or some other application method) and successively dried on the back-side of the substrate. Conventionally, the back-side silver or silver/aluminum paste 70 is screen printed onto the silicon first as two parallel strips (busbars) or as rectangles (tabs) ready for soldering interconnection strings (presoldered copper ribbons), the aluminum paste 60 is then printed in the bare areas with a slight overlap over the back-side silver or silver/aluminum 70. In some cases, the silver or silver/aluminum paste 60 is printed after the aluminum paste 70 has been printed. Firing is then typically carried out in a belt furnace for a period of 1 to 5 minutes with the wafer reaching a peak temperature in the range of 600 to 900° C. The front and back electrodes can be fired sequentially or cofired.

Consequently, as shown in FIG. 1F, molten aluminum from the paste dissolves the silicon during the firing process and then on cooling forms an eutectic layer that epitaxially grows from the silicon base 10, forming a p+ layer 40 containing a high concentration of aluminum dopant. This layer is generally called the back surface field (BSF) layer, and helps to improve the energy conversion efficiency of the solar cell. A thin layer of aluminum is generally present at the surface of this epitaxial layer.

In recent years, thinner silicon substrates are being studied as a means of reducing the costs of solar cells. The problem is that if the silicon substrate is made thinner, the back surface of the back-side electrode layer of aluminum paste composition becomes concave after firing due to the difference in thermal expansion coefficient between the silicon and aluminum, deforming the silicon substrate and causing warpage. One method of controlling this warpage is to reduce the applied amount of aluminum paste composition, thereby making a thinner back-side electrode layer. If the applied amount of aluminum paste composition is reduced, however, bumps and other defects are more likely to occur on the surface of the back-side electrode layer during firing. When multiple bumps and other defects are present on the back-side electrode layer, cracks and other problems may occur starting from the defect sites during transport of the solar cell or assembly as a module. Various techniques have been proposed for controlling such bumps and the like. For example, JP 2007-081059 proposes a technogy for controlling the occurrence of bumps and the like using a glass frit with a specific composition. As demand for higher-precision solar cells has risen in recent years, there is strong demand for techniques capable of controlling the occurrence of such defects while maintaining or achieving good electrical characteristics.

### SUMMARY OF THE INVENTION

The back-side electrode of the present invention adjacently formed on silicon layer of p-type solar cell comprises a conductive component comprising, before firing, (a) aluminum powder, (b) organic medium and (c) metal-containing component selected from the group consisting of (i) metal selected from the group consisting of Titanium(Ti), Manganese(Mn) and Cerium (Ce), and (ii) carbide, oxide, nitride, boride, carbonate, hydroxide and resinate of (i) metal.

In another aspect of the present invention, a method of forming a p-type silicon solar cell comprising the steps of: (I) applying an aluminum paste comprising (a) aluminum powder, (b)organic medium and (d) metal-containing component selected from the group consisting of (i) metal selected from the group consisting of Titanium(Ti), Manganese(Mn) and Cerium (Ce), and (ii) carbide, oxide, nitride, boride, carbonate, hydroxide, and resinate of (i) metal on the back-side of a silicon wafer having a p-type region, an n-type region and a p-n junction; and (II) firing the surface provided with the aluminum paste, whereby the wafer reaches a peak temperature of 600 to 900° C.

In another aspect of the present invention, a conductive paste (an aluminum paste) used for forming a back-side electrode of p-type solar cell comprises (a) aluminum powder, (b) organic medium and (c) metal-containing component selected from the group consisting of (i) metal selected from the group consisting of Titanium(Ti), Manganese(Mn) and Cerium (Ce), and (ii) carbide, oxide, nitride, boride, carbonate, hydroxide and resinate of (i) metal.

The present invention provides a solar cell having satisfactory electrical characteristics (open circuit voltage (Voc) and the like), wherein the occurrence of defects (bumps and the like) such as those described above is adequately controlled on the surface of the aluminum electrode.

### BRIEF DESCRIPTION OF THE FIGURES

FIG. 1A-1F show a process flow diagram illustrating exemplary the fabrication of a silicon sloar cell.

FIG. 1A shows a sectional view of p-type silicon substrate. FIG. 1B shows n-type diffusion layer was formed on the p-type silicon substrate. FIG. 1C shows the excess surface glass of the n-type diffusion layer was removed from the rest of the surfaces by etching. FIG. 1D shows a sectional view of antireflective coat formed on the n-type diffusion layer. FIG. 1E shows a sectional view of front-side silver paste screen formed over the antireflective coat. FIG. 1F shows a sectional view of BSF layer etc, formed on silicon substrate.

FIGS. 2A-2D explains the manufacturing process for manufacturing a silicon solar cell using a conductive aluminum paste of the present invention.

FIG. 2A shows a sectional view of Si substrate and electrodes formed on the light-receiving side of the Si substrate. FIG. 2B shows aluminum paste for back-side electrodes was printed on the Si Substrate. FIG. 2C shows a Ag or Ag/Al paste was printed. FIG. 2D shows the obtained solar cell.

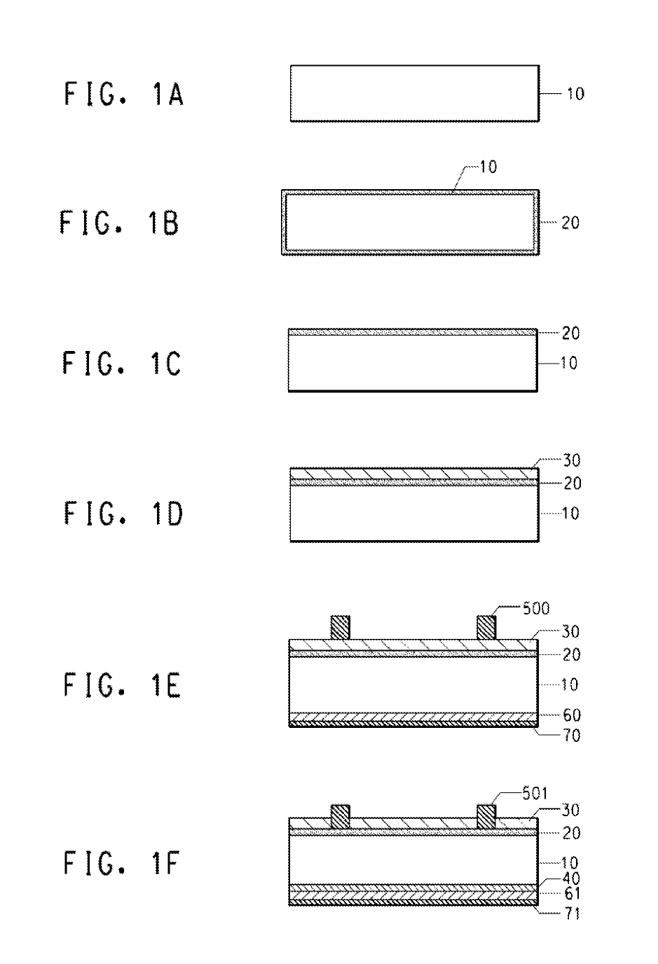

### DETAILED DESCRIPTION OF THE INVENTION

The present invention is explained in detail below.

### (Back-Side Electrode)

The back-side electrode of the present invention is formed adjacent to the silicon layer of a p-type solar cell from a conductive component (aluminum paste) comprising the following components (a) to (c).

### (a) Aluminum Powder

In one embodiment, the aluminum powder comprises atomized aluminum. The atomized aluminum may be atomized in either air or inert atmosphere. In one embodiment, the average particle size distribution of the atomized aluminum powder is in the range of 0.5 to 50 μm. In one embodiment, the average particle size distribution of the aluminum-containing powder is in the range of 1 to 20 μm. The form of the aluminum powder is not particularly limited, but a spherical or flake form or the like is preferred. The aluminum powder of the present invention is one containing aluminum metal in the amount of 85 wt % or more of the powder. In further embodiment, the aluminum powder may be further accompanied by other additive materials, such as, Mg, Ti, Cr, Mo, W, Mn, Ni, Cu, Ag, Zn, Si, Bi, Sb, Fe or a mixture thereof.

In one embodiment, the content of the (a) aluminum powder in the aluminum paste is preferably 60 to 85 wt %. In another embodiment, the content is preferably 65 to 80 wt %. In further embodiment, the content is preferably 70 to 80 wt %. If the content is less than 60 wt %, a good BSF layer may not be formed because the film thickness will be smaller after the aluminum paste is printed, resulting in an insufficient reaction phase between the silicon and aluminum or the like. If the content is over 85 wt %, on the other hand, a suitable viscosity for printing may not be obtained.

### (b) Organic Medium

A wide variety of inert viscous materials can be used as organic medium. The rheological properties of the organic medium must be such that they lend good application properties to the composition, including: stable dispersion of solids, appropriate viscosity and thixotropy for screen printing, appropriate wettability of the substrate and the paste solids, a good drying rate, and good firing properties. The organic vehicle used in the thick film composition of the present invention is preferably a nonaqueous inert liquid. Use can be made of any of various organic vehicles, which may or may not contain thickeners, stabilizers and/or other common additives. The organic medium is typically a solution of polymer(s) in solvent(s). Additionally, a small amount of additives, such as surfactants, may be a part of the organic medium. The most frequently used polymer for this purpose is ethyl cellulose. Other examples of polymers include ethylhydroxyethyl cellulose, wood rosin, mixtures of ethyl cellulose and phenolic resins, polymethacrylates of lower alcohols, and monobutyl ether of ethylene glycol monoacetate can also be used. The most widely used solvents are ester alcohols and terpenes such as alpha- or beta-terpineol or mixtures thereof with other solvents such as kerosene, dibutylphthalate, butyl carbitol, butyl carbitol acetate, hexylene glycol and high boiling alcohols and alcohol esters. In addition, volatile liquids for promoting rapid hardening after application on the substrate can be included in the vehicle. Various combinations of these and other solvents are formulated to obtain the viscosity and volatility requirements desired.

The content of polymer present in the organic medium is in the range 0.5 weight percent to 11 weight percent of the total composition. The aluminum paste of the present invention may be adjusted to a predetermined, screen-printable viscosity with the organic polymer containing medium.

In one embodiment, the content (wt %) of the (b) organic medium is preferably 17 to 70 wt % per 100 wt % of the (a) aluminum powder. In another embodiment, the content (wt %) of (b) is preferably 25 to 40 wt % per 100 wt % of the (a) aluminum powder. If the content (wt %) is less than 17 wt % per 100 wt % of the (a) aluminum powder, a suitable viscosity for printing may not be obtained. On the other hand, if the content (wt %) is over 70 wt % per 100 wt % of the (a) aluminum powder, a good BSF layer may not be formed because the film thickness will be smaller after the aluminum paste is printed, resulting in an insufficient reaction phase between the silicon and aluminum or the like.

### (c) Metal-Containing Component

In one embodiment, the metal-containing component is selected from the group consisting of (i) metal selected from the group consisting of Titanium(Ti), Manganese(Mn) and Cerium (Ce), and (ii) carbide, oxide, nitride, boride, carbonate, and resinate of (i) metal particles.

By including this (c) metal-containing component in the aluminum paste, it is possible to effectively control the occurrence of bumps and other defects on the aluminum electrode surface in the present invention, while maintaining or achieving good open circuit voltage (Voc) in the resulting solar cell. One kind of (c) metal-containing component may be included, or 2 or more may be included.

In one embodiment, the content (wt %) of the metal in the (c) metal-containing component is preferably 0.05 to 6.0 wt % per 100 wt % of the (a) aluminum powder. In another embodiment, the content is preferably 0.05 to 3.0 wt %. In further embodiment, the content is preferably 0.1 to 2.0 wt %.

If the content (wt %) of the (c) metal-containing component is less than 0.05 wt %, the effects of including the metal-containing component may not be sufficient, while the intrinsic electrical characteristics of the aluminum paste may be adversely affected if the content (wt %) is over 6.0 wt %. The form of the metal-containing component is not particularly limited, and examples include spherical, flake and needle forms, as well as liquid, viscous and granular forms and the like in the case of an organic metal.

The particle size of a powder of the metal-containing component is not particularly limited, but in one embodiment the average particle size (D50) is 0.05 to 30 μm for example. In another embodiment it is 0.1 to 10 μm. If the average particle size (D50) is less than 0.05 μm, there may be problems of dispersibility in the paste. If the average particle size is above 30 μm, on the other hand, the applied film may have a coarser surface, and voids and other defects may occur.

The method of manufacturing a powder of the metal-containing component is not particularly limited, and examples include wet reduction of metal salts, atomization, and in the case of oxides, dehydration of metal hydroxides and decarbonation of metal carbonates. In the case of a carbonate, a dehydration reaction of a metal hydroxide with carbon dioxide is also possible. Various other known methods can also be used favorably.

Each metal in the metal-containing component (titanium, manganese and cerium) has a purity of 97% or more as a simple substance.

(c-1) Titanium (Ti)

In one embodiment, when the metal contained in the (c) metal-containing component is titanium (Ti) as a simple substance or a carbide, oxide, nitride, boride, carbonate, hydroxide and/or resinate compound of titanium (Ti), the content (wt %) of titanium (Ti) is preferably 0.05 to 3.0 wt % per 100 wt % of the (a) aluminum powder. In another embodiment, the content is preferably 0.05 to 1.0 wt %. If the content (wt %) is less than 0.05 wt %, the effects of including the metal-containing component may not be sufficient. If the content (wt %) is over 3.0 wt %, on the other hand, the photoelectric conversion efficiency may decline due to decreased open circuit voltage (Voc) or the like. When the titanium is a compound, the content (wt %) of the titanium is a value calculated based on the weight of only the titanium in the compound. Specific examples of such titanium compounds include the oxides TiO, Ti₂O₃ and TiO₂, the boride TiB₂, the carbide TiC, the nitride TiN and the hydroxide Ti(OH)₃. Specific examples of composite oxides and organometallic compounds are described below. One of these may be used alone, or 2 or more may be combined.

(c-2) Manganese (Mn)

In one embodiment, when the metal contained in the (d) metal-containing component is manganese (Mn) as a simple substance, or a carbide, oxide, nitride, boride, carbonate, hydroxide and/or resinate compound of manganese (Mn), the content (wt %) of manganese (Mn) is preferably 0.05 to 3.0 wt % per 100 wt % of the (a) aluminum powder. In another embodiment, the content is preferably 0.05 to 1.0 wt %. If this content (wt %) is less than 0.05 wt %, the effects of including the metal-containing component may not be sufficient. If the content is over 3.0 wt %, on the other hand, the photoelectric conversion efficiency may decline due to decreased open circuit voltage (Voc) or the like. When the manganese is a compound, the content (wt %) of the manganese is a value calculated based on the weight of only the manganese in the compound. Specific examples of such manganese compounds include the oxides MnO, MnO₂, Mn₂O₃ and Mn₃O₄, the carbonate MnCO₃, the boride MnB, and the hydroxide Mn(OH)₂. Specific examples of composite oxides and organometallic compounds are described below. One of these may be used alone, or 2 or more may be combined.

(c-3) Cerium (Ce)

In one embodiment, when the metal contained in the (d) metal-containing component is cerium (Ce) as a simple substance, or a carbide, oxide, nitride, boride, carbonate, hydroxide and/or resinate compound of cerium (Ce), the content (wt %) of cerium (Ce) is preferably 0.05 to 6.0 wt % per 100 wt % of the (a) aluminum powder. In another embodiment, the content is preferably 0.2 to 3.0 wt %. If this content (wt %) is less than 0.05 wt %, the effects of including the metal-containing component may not be sufficient. If the content (wt %) is over 6.0 wt %, on the other hand, the photoelectric conversion efficiency may decline due to decreased open circuit voltage (Voc) or the like. When the cerium is a compound, the content (wt %) of the cerium is a value calculated based on the weight of only the cerium in the compound. Specific examples of such cerium compounds include the oxides CeO₂ and Ce₂(CO)₃, the hydroxide Ce(OH)₄, the boride CeB₆, and the carbide CeC₂. Specific examples of composite oxides and organometallic compounds are described below. One of these may be used alone, or 2 or more may be combined.

(c-4) Composite Oxides

When the metal-containing component is a composite oxide as described above, specific examples include SrTiO₃, BaTiO₃, CaTiO₃, MnCr₂O₄, MnTiO₃, MnWO₄ and the like. When these composite oxides are used, the content thereof may preferably be the same as the content given above for each metal, according to the type of metal (such as Ti, Mn, Ce) contained in the composite oxide. In the case of SrTiO₃, for example, the content is preferably similar to the content described for titanium (Ti). That is, it is preferably 0.05 to 3.0 wt % per 100 wt % of the (a) aluminum powder. In another embodiment, the content is preferably 0.05 to 1.0 wt %.

(c-5) Organometallic Compounds

When the metal-containing component is an organometallic compound as described above, specific examples include the organometallic compounds represented by the following formulae:

Me(AR)n (I);

Me(R)n (II); and

Me(B−R)n (III),

where in formulae (I) to (III), Me is a metal selected from titanium (Ti), manganese (Mn) and cerium (Ce). In Formula (I), A represents —O—, and R represents a C₄₋₁₈ straight, branched or cyclic hydrocarbon. Examples include Me(OiC₃H₇)n, Me(OC₂H₅)n and the like. In Formula (II), R represents a C₄₋₁₈ straight, branched or cyclic hydrocarbon. When R is a hydrocarbon, its bonds may include a carbonyl (—C(═O)O—) group or ether (—O—) group or the like. Examples include Me(C₆H₅)n, Me(C₁₁H₁₉O₂)n and the like. In Formula (III), B represents —O—CO— and R represents a C₁₁₋₁₈ straight or branched hydrocarbon. Examples include Me(O—CO—C₇H₁₅)n and Me(O—CO—C₁₁H₂₃)n. Specific examples of this organometallic compound include Ti(OCH₃)₄, Ti(OC₂H₅)₄, Ti(OiC₄H₉)₄, Mn(OiC₃H₇)₂ and Ce(OiC₃H₇)₂.

### (d) Other Additive(s)

The conductive component may comprise glass frit, Strontium (Sr), Stibium (Sb), or one or more organic additives, for example, surfactants, thickeners, rheology modifiers and stabilizers.

(d-1) Glass Frits

Generally, the function of the glass frit in an aluminum paste is primarily to provide a means to increase the efficiency by which the silicon is accessed by the molten aluminum during the firing process. In addition to this function, glass frit provides some additional cohesion and adhesion properties to the substrate. The glass frit affects the bowing of the aluminum layer in the finished cell. The glass frit can also increase the alloying depth of the aluminum into the silicon, therefore enhancing or increasing the aluminum dopant concentration in the eutectically grown silicon layer.

The glass frit is, in an embodiment, chosen based on the effectiveness that they have on improving the electrical performance of the aluminum thick film paste without compromising other considerations such as environmental legislation or public desire to exclude heavy metals of potential environmental concern.

In one embodiment, the content (wt %) of glass frit is 0.1 to 5.0 wt % per 100 wt % of the (a) aluminum powder. In another embodiment, the content (wt %) of glass frit is 0.2 to 3.0 wt % per 100 wt % of the (a) aluminum powder. In further embodiment, the content (wt %) of glass frit is 0.3. to 2.0 wt % per 100 wt % of the (a) aluminum powder. If the content (wt %) of glass frit is less than 0.1 wt % per 100 wt % of the (a) aluminum powder, the electrical characteristics (open circuit voltage (Voc)) may decline, while if the content exceeds 5.0 wt % per 100 wt % of the (a) aluminum powder, bumps and other defects may occur on the aluminum film after firing.

Glass frit useful for the present invention is known in the art. Some examples include borosilicate and aluminosilicate glasses. Examples further include combinations of oxides, such as: B₂O₃, SiO₂, Al₂O₃, CaO, BaO, ZnO, Na₂O, Li₂O, SrO, TiO₂, Ta₂O₃, Bi₂O₃, Sb₂O₃, K₂O, PbO and ZrO or combinations of fluoride, such as: CaF₂, BaF₂, ZnF₂, NaF, LiF, SrF₂, TiF₄, TaF₆, BiF₃, SbF₅, KF, PbF₂ and ZrF₄, which may be used independently or in combination to form glass frit composition. The conventional glass frit preferably used are the borosilicate frits, such as lead borosilicate frit, bismuth, cadmium, barium, calcium, or other alkaline earth borosilicate frits. The preparation of such glass frit composition is well known and consists, for example, in melting together the constituents of the glass in the form of the oxides of the constituents and pouring such molten composition into water to form the frit. The batch ingredients may, of course, be any compounds that will yield the desired oxides under the usual conditions of frit production. For example, boric oxide will be obtained from boric acid, silicon dioxide will be produced from flint, barium oxide will be produced from barium carbonate, etc. In one embodiment, the conductive component comprises at least one glass frit composition wherein upon firing said glass frit composition undergoes recrystallization or phase separation and liberates a frit with a separated phase that has a lower softening point than the original softening point. Thus, the thick film composition comprising such a glass frit composition upon processing gives lower bowing properties. In one embodiment, the glass frit is a lead-free glass frit composition which, upon firing, undergoes recrystallization or phase separation and liberates a frit with a separated phase that has a lower transition point than the original transition point. Mixtures one or more frits are possible. The glass is preferably milled in a ball mill with water or inert low viscosity, low boiling point organic liquid to reduce the particle size of the frit and to obtain a frit of substantially uniform size. It is then settled in water or said organic liquid to separate fines and the supernatant fluid containing the fines is removed. Other methods of classification may be used as well.

The glasses are prepared by conventional glassmaking techniques, by mixing the desired components in the desired proportions and heating the mixture to form a melt. As is well known in the art, heating is conducted to a peak temperature and for a time such that the melt becomes entirely liquid and homogeneous. The desired glass transition temperature is in the range of 325 to 650° C.

In one embodiment, the average particle size (D50) of the glass frit composition be 0.1-10 μm. The reason for this is that smaller particles having a high surface area tend to adsorb the organic materials and thus impede clean decomposition. On the other hand, larger size particles tend to have poorer sintering characteristics.

(d-2) Strontium (Sr)

The effect of suppressing bumps and other defects on the surface of the back-side electrode after firing is enhanced by further including a specific amount of strontium (Sr) as a simple substance or a carbide, oxide, nitride, boride, carbonate and/or resinate of strontium in the conductive component. This also serves to confer superior anti-wetting properties on the solar cell.

From the standpoint of effectively suppressing bumps and other defects, the content (wt %) of strontium (Sr) is preferably 0.05 to 8.0 wt % per 100 wt % of the (a) aluminum powder. In another embodiment, the content is preferably 0.1 to 6.0 wt %. In further embodiment, the content is preferably 0.1 to 4.0 wt %. If the content (wt %) is less than 0.05 wt %, bumps and other defects may not be sufficiently suppressed. If the content (wt %) exceeds 8.0 wt %, on the other hand, there may be a drop in open circuit voltage (Voc) associated with the BSF layer, detracting from the electrical characteristics.

On the other hand, in one embodiment the content (wt %) of strontium (Sr) is preferably 0.2 to 6.0 wt % per 100 wt % of the (a) aluminum powder from the standpoint of conferring better hot water resistance. In another embodiment, the content is preferably 0.4 to 5.0 wt %. In further embodiment, the content is preferably 0.4 to 4.0 wt %. If the content (wt %) is less than 0.04 wt %, the effect on hot water resistance may not be sufficient. If the content (wt %) exceeds 6.0 wt %, on the other hand, the open circuit voltage (Voc) may decline. When the strontium is a compound, the strontium content (wt %) is a value calculated based on the weight of only the strontium in the compound. Specific examples of such strontium compounds include the oxide SrO, the carbonate SrCO₃, and the hydroxide Sr(OH)₂. One of these may be used alone, or 2 or more may be combined. Hot water resistance is a form of resistance that is currently considered an important type of corrosion resistance in severe environments. For example, a sample having aluminum electrodes is dipped for 10 minutes in specific distilled water at about 80° C., and is evaluated based on the visual observation of bubbles or gases which are generated from the reaction between aluminum (from the sample in the hot water) and the hot water in 10 minutes.

(d-3) Stibium (Sb)

Similarly, the effect of suppressing bumps and other defects on the surface of the back-side electrode after firing is enhanced by further including a specific amount of stibium (Sb) as a simple substance or a carbide, oxide, nitride, boride, carbonate and/or resinate of strontium in the conductive component. This also serves to confer superior anti-wetting properties on the solar cell.

From the standpoint of effectively suppressing bumps and other defects, the content (wt %) of stibium (Sb) is preferably 0.04 to 3.0 wt % per 100 wt % of the (a) aluminum powder. In another embodiment, the content is preferably 0.05 to 2.0 wt %. In further embodiment, the content is preferably 0.08 to 1.0 wt %. If the content (wt %) is less than 0.04 wt %, bumps and other defects may not be sufficiently suppressed. If the content (wt %) exceeds 3.0 wt %, on the other hand, there may be a drop in open circuit voltage (Voc) associated with the BSF layer, detracting from the electrical characteristics.

On the other hand, in one embodiment the content (wt %) of stibium (Sb) is preferably 0.04 to 3.0 wt % per 100 wt % of the (a) aluminum powder from the standpoint of conferring better hot water resistance. In another embodiment, the content is preferably 0.05 to 2.0 wt %. In further embodiment, the content is preferably 0.08 to 1.0 wt %. If the content (wt %) is less than 0.04 wt %, the effect on hot water resistance may not be sufficient. If the content (wt %) exceeds 3.0 wt %, on the other hand, the open circuit voltage (Voc) may decline. When the stibium is a compound, the stibium content (wt %) is a value calculated based on the weight of only the stibium in the compound. Specific examples of such stibium compounds include the oxides Sb₂O₃, Sb₂O₄ and Sb₂O₅. Other examples include organic resinate compounds such as those described below. One of these may be used alone, or 2 or more may be combined.

(d-4) Organic Additive(s)

The conductive component (aluminum paste) may further comprise one or more organic additives, for example, surfactants, thickeners, rheology modifiers and stabilizers. The organic additive(s) may be part of the organic medium. However, it is also possible to add the organic additive(s) separately when preparing the aluminum pastes. The organic additive(s) may be present in the aluminum pastes of the present invention in a total proportion of, for example, 0 to 10 wt(%), based on total aluminum paste composition.

The conductive component (aluminum paste) explained above is typically conveniently manufactured by mechanically mixing, a dispersion technique that is equivalent to the traditional roll milling. Roll milling or other mixing technique can also be used. The conductive component is preferably spread on the desired part of the back face of a solar cell by screen printing; in spreading by such a method, it is preferable to have a viscosity in a prescribed range. Other application methods can be used such as silicone pad printing. The viscosity of the conductive component (aluminum paste) is preferably 20-100 Pa·S when it is measured at a spindle speed of 10 rpm and 25° C. by a utility cup using a Brookfield HBT viscometer and #14 spindle.

The silver/aluminum or silver film can be cofired with the conductive component at the same time in a process called cofiring.

### (Solar Cell)

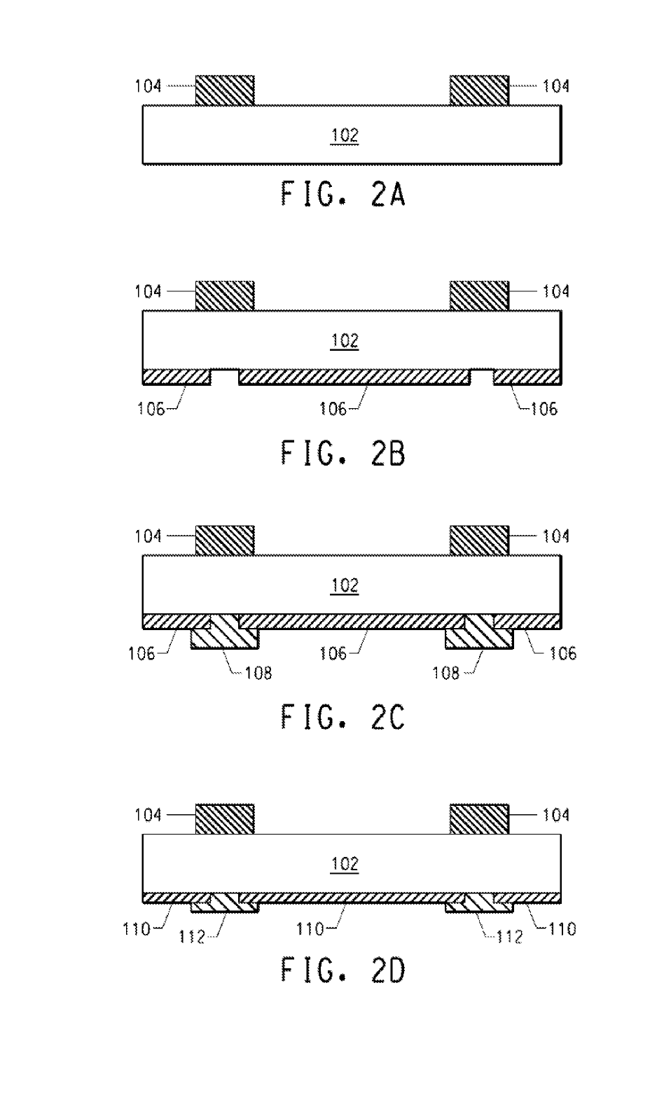

Next, an example in which a solar cell is prepared using the conductive component (aluminum paste) is explained, referring to the Figure (FIG. 2).

First, a Si substrate 102 is prepared. On the light-receiving side face (surface) of the Si substrate, normally with the p-n junction close to the surface, electrodes (for example, electrodes mainly composed of Ag) 104 are installed (FIG. 2A).

On the back-side of the substrate, the conductive component (aluminum paste) used for forming a back-side electrode of p-type solar cell of the present invention 106 are spread by screen printing using the pattern(FIG. 2B). Then, a Ag or Ag/Al electro conductive paste (although it is not particularly limited as long as it is used for a solar cell, for example, PV202 or PV502 or PV583 or PV581 (commercially available from E. I. du Pont de Nemours and Company)) 108 are spread by screen printing using the pattern that enable slight overlap with the conductive component 106 referred to above (FIG. 2C), then dried. The drying temperature of each paste is preferably 150° C. or lower in a static drier for 5-10 minutes.

In one embodiment, the aluminum paste has a dried film thickness of 15-60 μm. In another embodiment, the thickness of the aluminum paste is preferably 15-30 μm. Also, the overlapped part of the aluminum paste and the silver/aluminum electro conductive paste is preferably about 0.5-2.5 mm. Next, the substrate obtained is fired at a temperature of 600-900° C. for about 1 min -15 min, for instance, so that the desired solar cell is obtained (FIG. 2D). An electrode is formed from the composition(s) of the present invention wherein said composition has been fired to remove the organic medium and sinter the glass frit. The solar cell obtained using the aluminum paste of the present invention, as shown in FIG. 2D has electrodes 104 on the light-receiving face (surface) of the substrate (for example, Si substrate) 102, Al electrodes 110 mainly composed of Al and silver/aluminum electrodes 112 mainly composed of Ag and Al, on the back face.

The present invention will be discussed in further detail by giving practical examples. The scope of the present invention, however, is not limited in any way by these practical examples.

### EXAMPLES

The examples cited here relate to aluminum pastes fired onto conventional solar cells that have a silicon nitride anti-reflection coating and front side n-type contact thick film silver conductor.

The present invention can be applied to a broad range of semiconductor devices, although it is especially effective in light-receiving elements such as photodiodes and solar cells. The discussion below describes how a solar cell is formed utilizing the paste(s) of the present invention and how it is tested for its technological properties.

### (1) Manufacture of Solar Cell

A solar cell was formed as follows:

### (i) Aluminum Paste(s) Preparation

The aluminum paste was produced using the following materials.

<Materials>

(a) Aluminum powder: (The average particle size distribution of the aluminum-containing powder(D50)=5 μm)

(b) Organic medium: (Resin solution comprising ethyl cellulose resin dissolved in terpineol)

(c) Metal-containing component: (Described in the corresponding columns of Table 1)

(d) Glass frits: (Glass composed primarily of SiO₂—B₂O₃—Bi₂O₃—ZnO, with BaO, Al₂O₃ and the like added thereto)

<Procedure of the Preparations>

Aluminum paste preparations were accomplished with the following procedure. Aluminum powder, glass frit, and metal-containing component (described in the corresponding columns of Table 1) were dispersed in the organic medium and mixed by mixer for 120 minutes. The content of aluminum powder, glass frit, and metal-containing component paste are shown in Table 1. The degree of dispersion was measured by fineness of grind (FOG). A typical FOG value was generally equal to or less than 20/10 for a conductor.

TABLE 1

| | (a) Al | (c) Metal-containing | | (d) Glass | (b) Organic |
|---|---|---|---|---|---|
| | Powder | component | | Frits | medium |
| | (wt %) | Type | wt % | wt % | (wt %) |
| Ex. 1 | 100 | Titanium octylate | 0.99 | — | 22.5 |
| Ex. 2 | 100 | Mn (OiC₃H₇)₂ | 1.24 | — | 22.5 |
| Ex. 3 | 100 | Ce(OiC₃H₇)₃ | 0.252 | 1.2 | 22.5 |
| Ex. 4 | 100 | CeO2 | 0.5 | 0.58 | 22.5 |
| Ex. 5 | 100 | CeO2 | 2 | 0.58 | 22.5 |
| Co. Ex 1 | 100 | — | — | 0.7 | 22.5 |

### (ii) Solar Cell Preparation (Sample Preparation)

On the front-side of a Si substrate (200 μm thick multicrystalline silicon wafer of area 14.44 cm² p-type (boron) bulk silicon, with an n-type diffused POCl₃ emitter, surface texturized with acid, SiNₓ anti-reflective coating (ARC) on the wafer's emitter applied by CVD), a 20 μm thick silver electrode on the front surface (PV159 Ag composition commercially available from E. I. Du Pont de Nemours and Company) was printed and dried. Then, aluminum pastes for the back-side electrode of solar cell, prepared in (1) was screen-printed at dried film thickness of 40 μm. The screen-printed aluminum pastes were dried before firing.

The printed wafers were then fired in a Despatch furnace at a belt speed of 550 cm/min. The wafers reaching a peak temperature of 740° C. After firing, the metalized wafer became a functional photovoltaic device.

### (2) Test Procedures

### a) Electric Performance

a-1) Measurement of Open Circuit Voltage (Voc)

Each sample of solar cells (Examples 1-5 and Comparative Example 1) formed according to the method described above were placed in a commercial I-V tester (supplied by NPC.) for the purpose of measuring light conversion efficiencies. The lamp in the I-V tester simulated sunlight of a known intensity (approximately 1000 W/m²) and illuminated the emitter of the cell. The metalizations printed onto the fired cells were subsequently contacted by four electrical probes. The photocurrent (Voc, open circuit voltage; Isc, short circuit current) generated by the solar cells was measured over arrange of resistances to calculate the I-V response curve. Voc alues were subsequently derived from the I-V response curve.

a-2) Evaluation Based on Open Circuit Voltage Value (Voc)

The Voc values obtained from the sample measurements for each example as described above were evaluated in comparison with the open circuit voltage value (Voc) obtained from the sample measurements of Comparative Example 1. The results are shown in Table 2. Each open circuit voltage value (Voc) was considered substantially acceptable if the reduction in Voc was within −3% in comparison with the sample of Comparative Example 1.

### b) Observation and Evaluation of Bumps

(1) Bumps were observed and evaluated as described below for the sample of Comparative Example 1 and the samples of Examples 1 to 5 obtained in (1) (ii) above.

That is, the aluminum electrode surface of each sample was checked visually to confirm the presence or absence of bumps occurring on the surface of the aluminum electrode after firing. This was evaluated according to the following criteria. The results are shown in Table 2.

### <Evaluation Criteria>

Excellent: Slight bumps observed in some areas on the aluminum electrode surface, but at a level that presents no problems for practical use.

Good/marginal: Some bumps observed on the aluminum electrode surface, but at a level that presents no fundamental problems for practical use.

Bad: Bumps observed on the aluminum electrode surface at a level that presents problems for practical use.

TABLE 2

| | | Metal wt % in | a-2) Voc | |
|---|---|---|---|---|
| | Metal | Metal | (delta % | |
| | Compound | Compound | vs STD) | b) Bumps |
| Ex. 1 | Titanium | 0.11 | 0.19 | Good-Marginal |
| | octylate | | | |
| Ex. 2 | Mn (OiC₃H₇)₂ | 0.13 | −1.80 | Excellent |
| Ex. 3 | Ce(OiC₃H₇)₃ | 0.25 | −1.57 | Excellent |
| Ex. 4 | CeO₂ | 0.41 | 0.66 | Good-Marginal |
| Ex. 5 | CeO₂ | 1.63 | 1.13 | Excellent |
| Co. Ex 1 | — | — | STD | Bad |

What is claimed is:

1. A back-side electrode adjacently formed on silicon layer of p-type solar cell, comprises a conductive component comprising, before firing, (a) aluminum powder, (b) organic medium and (c) metal-containing component selected from the group consisting of (i) metal selected from the group consisting of Titanium(Ti), Manganese(Mn) and Cerium (Ce), and (ii) carbide, oxide, nitride, boride, carbonate, hydroxide and resinate of (i) metal.

2. The back-side electrode according to claim 1, wherein the conductive component further comprising glass frit and the weight ratio of glass frit for (a) aluminum powder is 0.1/100˜5.0/100.

3. The back-side electrode according to claim 1, wherein the weight ratio of (i) metal for (a) aluminum powder ((i)metal/(a) aluminum powder) is 0.04/100˜6.0/100.

4. The back-side electrode according to claim 1, wherein the (i) metal is Titanium (Ti) and the weight ratio of Titanium (Ti) for (a) aluminum powder (Titanium (Ti)/(a) aluminum powder) is 0.05/100˜3.0/100.

5. The back-side electrode according to claim 1, wherein the metal is Manganese (Mn) and the weight ratio of Manganese (Mn) for (a) aluminum powder (Manganese (Mn)/(a) aluminum powder) is 0.05/100˜3.0/100.

6. The back-side electrode according to claim 1, wherein the metal is Cerium (Ce) and the weight ratio of Cerium (Ce) for (a) aluminum powder (Cerium (Ce)/(a) aluminum powder) is 0.05/100˜6.0/100.

7. The back-side electrode according to claim 1, wherein the content of (b) organic medium is 17-70(wt %), based on the total weight of the conductive component.

8. A method of forming a p-type silicon solar cell comprising the steps:
(I) applying an aluminum paste comprising (a) aluminum powder, (b) organic medium and (c) metal-containing component selected from the group consisting of (i) metal selected from the group consisting of Titanium(Ti), Manganese(Mn) and Cerium (Ce), and (ii) carbide, oxide, nitride, boride, carbonate, and resinate of (i) metal particles on the back-side of a silicon wafer having a p-type region, an n-type region and a p-n junction; and
(II) firing the surface provided with the aluminum paste, whereby the wafer reaches a peak temperature of 600 to 900° C.

9. The method of claim 8, wherein the application of the aluminum paste is performed by printing.

10. The method of claim 8, wherein firing is performed as cofiring together with other front-side and/or back-side metal pastes that have been applied to the silicon wafer to form front-side and/or back-side electrodes thereon during firing.

11. Silicon solar cells made by the method of claim 8.

12. An aluminum paste used for forming a back-side electrode of p-type solar cell comprises (a) aluminum powder, (b) organic medium and (c) metal-containing component selected from the group consisting of (i) metal selected from the group consisting of Titanium(Ti), Manganese(Mn) and Cerium (Ce), and (ii) carbide, oxide, nitride, boride, carbonate, hydroxide, and resinate of (i) metal.
